(19) United States
(12) Patent Application Publication
(10) Pub. No.: US 2016/0198582 A1
(43) Pub. Date: Jul. 7, 2016

(54) FLEXIBLE DISPLAY

(71) Applicant: Samsung Display Co., Ltd., Yongin-city (KR)

(72) Inventors: Hae Ju YUN, Hwaseong-si (KR); Yong Seok Kim, Seoul (KR); Kwang Soo Bae, Suwon-si (KR); Dae Ho Song, Hwaseong-si (KR)

(21) Appl. No.: 14/789,128

(22) Filed: Jul. 1, 2015

(30) Foreign Application Priority Data
Jan. 2, 2015 (KR) 10-2015-0000221

(51) Int. Cl. H05K 5/02; H01F 7/02; H05K 5/00

(52) U.S. Cl. CPC H05K 5/0217; H05K 5/0017; H01F 7/02

(57) ABSTRACT

A flexible display is disclosed. In one aspect, the flexible display includes a display panel including a front surface configured to display an image and a rear surface opposing the front surface of the display panel. The flexible display also includes first and second magnets positioned on the rear surface and first and second bonding layers respectively interposed between the display panel and the first and second magnets.

### CROSS-REFERENCE TO RELATED APPLICATION

This application claims priority to and the benefit of Korean Patent Application No. 10-2015-0000221 filed in the Korean Intellectual Property Office on Jan. 2, 2015, the entire contents of which are incorporated herein by reference.

### BACKGROUND

1. Field

The described technology generally relates to a flexible display panel.

2. Description of the Related Art

Advances in communication technologies and semiconductor and optical technologies have resulted in the tremendous popularity of Internet-accessible devices such as smartphones, tablet computers, and the like which have had a lasting impact on how mobile technologies are used. These advances have brought about remarkable innovation in the scientific technologies.

Tablet computers have an advantage over smaller mobile devices in that they include a large display screen. However, tablet computers also have the disadvantage of being inconvenient to carry due to their weight and size.

In order to address this problem, flexible displays are being actively developed.

### SUMMARY OF CERTAIN INVENTIVE ASPECTS

One inventive aspect is a flexible display including: a display panel including a front surface on which an image is displayed and a rear surface positioned at an opposite side of the front surface; a magnet part positioned on the rear surface; and a bonding part positioned between the display panel and the magnet part so as to bond the display panel and the magnet part.

The bonding part can include an insulating material that insulates the display panel and the magnet part.

The magnet part can include a first magnet and a second magnet that are positioned at positions different from each other on the rear surface.

The first magnet and the second magnet can have polarities different from each other and can be in contact with each other so as to fold the display panel in a direction of the rear surface.

The first magnet and the second magnet can have the same polarity.

The display panel can be attached to and detached from a structure including a third magnet and a fourth magnet, and the third magnet can be attached to the first magnet and the fourth magnet can be in contact with the second magnet.

The first magnet and the third magnet can have polarities different from each other and the second magnet and the fourth magnet can have polarities different from each other.

The structure can be configured in a circular shape, an oval shape, or an N-polygonal shape.

The magnet part can further include a fifth magnet and a sixth magnet that are positioned at positions different from each other on the rear surface.

The fifth magnet can have polarity different from that of the first magnet and the sixth magnet can have polarity different from that of the second magnet.

The first magnet is in contact with the fifth magnet and the second magnet is in contact with the sixth magnet, such that the display panel can be folded in the direction of the rear surface.

The flexible display can further include an insulating layer between the bonding part and the magnet part.

The display panel and the magnet part can be formed so as to be spaced apart from each other by 100 Å or more.

The display panel can be bent or curved by external force.

The display panel can include: a pixel electrode; a roof layer positioned so as to face the pixel electrode; and a liquid crystal layer having a plurality of microcavities formed so as to be partitioned from each other between the pixel electrode and the roof layer, wherein the microcavity is made of liquid crystal molecules.

The flexible display can further include a common electrode formed so as to be electrically insulated from the pixel electrode.

The flexible display can further include a liquid crystal injection hole formed in the roof layer so as to expose a portion of the microcavity; and an overcoat formed on the roof layer so as to cover the injection hole and sealing the microcavity.

Another aspect is a flexible display, comprising a display panel including a front surface configured to display an image and a rear surface opposing the front surface; first and second magnets positioned on the rear surface of the display panel; and first and second bonding layers respectively interposed between the display panel and the first and second magnets and bonding the display panel to the magnet, wherein the first and second magnets are arranged at different positions on the rear surface of the display panel, and wherein the display panel is configured to be folded such that different polarities of the first and second magnets are magnetically aligned.

In exemplary embodiments, each of the bonding layers is formed of an insulating material and insulates the display panel from the first and second magnets. The first magnet and the second magnet can be configured to contact each other when the display panel is folded in the direction of the rear surface of the display panel. The display panel can be configured to be attached to and detached from a structure including a third magnet and a fourth magnet, the third magnet can be configured to be attached to the first magnet, and the fourth magnet can be configured to be attached to the second magnet.

In exemplary embodiments, the first magnet and the third magnet have polarities that are different from each other and wherein the second magnet and the fourth magnet have polarities that are different from each other. The structure can have a cylindrical shape having a cross-section with a circle or an oval shape, or a prism having an N-sided polygonal cross-section. The at least one magnet can further include a fifth magnet and a sixth magnet that are arranged at different positions from each other on the rear surface of the display panel. The fifth magnet can have polarity that is different from that of the first magnet and the sixth magnet can have polarity that is different from that of the second magnet. The first magnet can be configured to contact the fifth magnet and the second magnet can be configured to contact the sixth magnet, when the display panel is folded in the direction of the rear surface of the display panel.

In exemplary embodiments, the flexible display further comprises an insulating layer interposed between the bonding layers and the magnets. The display panel and the magnets can be spaced apart from each other by about 100 Å or more. The display panel can be configured to be bent or curved by external force. The display panel can include a plurality of pixel electrodes; a cover layer opposing the pixel electrodes so as to form a plurality of microcavities, wherein the microcavities are separated from each other; and a plurality of liquid crystal layers respectively arranged in the microcavities.

In exemplary embodiments, the flexible display further comprises a common electrode electrically insulated from the pixel electrode. The flexible display can further comprise a plurality of liquid crystal injection holes formed in the cover layer, wherein each of the liquid crystal injection holes is connection to a corresponding one of the microcavities; and an overcoat formed on the cover layer so as to cover the injection holes and seal the microcavities.

In addition to the above-mentioned objects, other features and advantages of the described technology may be apparently understood by those skilled in the art to which the described technology pertains from the following description.

According to at least one embodiment, there are the following effects.

According to at least one embodiment, the display device can be modified to various forms by including the plurality of magnets on the rear surface of the display and attaching and detaching the plurality of magnets positioned at different positions and having different polarities to and from the rear surface of the display device.

Additionally, other features and advantages according to the described technology can be newly understood through exemplary embodiments.

### BRIEF DESCRIPTION OF THE DRAWINGS

FIG. 1 is a cross-sectional view of a display device according to an exemplary embodiment.

FIG. 2 is a plan view of a display device according to an exemplary embodiment implemented in a cylindrical shape.

FIG. 3 is a perspective view of a display device according to an exemplary embodiment implemented in a cylindrical shape.

FIG. 4 is a perspective view of a structure that can be attached to and detached from a display device according to an exemplary embodiment.

FIG. 5 is a diagram illustrating various shapes of a structure that can be attached to and detached from a display device according to an exemplary embodiment.

FIG. 6 is a plan view of a display device according to another exemplary embodiment.

FIG. 7 is a plan view of a modified example of a display device according to another exemplary embodiment.

FIG. 8 is a cross-sectional view of a display device according to still another exemplary embodiment.

FIG. 9 is a plan view showing a display panel according to an exemplary embodiment.

FIG. 10 is a plan view showing one pixel of the display panel according to an exemplary embodiment.

FIG. 11 is a cross-sectional view showing a portion of the display panel according to an exemplary embodiment taken along line IV-IV of FIG. 9.

FIG. 12 is a cross-sectional view showing a portion of the display panel according to an exemplary embodiment taken along line V-V of FIG. 9.

### DETAILED DESCRIPTION OF CERTAIN INVENTIVE EMBODIMENTS

Flexible displays are devices which can have their shape altered. Certain flexible displays are rollable into a cylindrical shape or can be curved or bendable similar to paper and can have variously shaped perimeters.

In addition, due to the flexibility of the substrate, these displays are stronger and less likely to be broken than the standard display. In some implementations, a thin and light substrate such as plastic is used in order to form a thin-profile, light display.

A basic type of flexible display can be folded in half, reducing its area to be more easily transported. However, a flexible display which can be made to conform to various shapes and have multiple or continuous folds is desirable.

The described technology will be described more fully hereinafter with reference to the accompanying drawings in which exemplary embodiments are shown. As those skilled in the art would realize, the described embodiments can be modified in various different ways, all without departing from the spirit or scope of the described technology.

In the drawings, the thickness of layers, films, panels, regions, etc., may be exaggerated for the sake of clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a display device according to an exemplary embodiment will be schematically described.

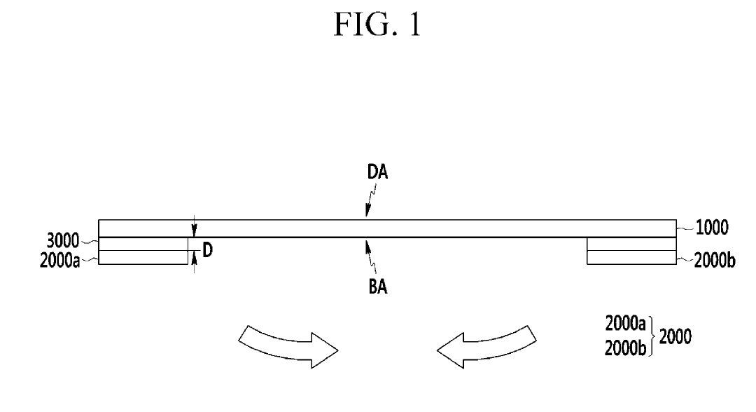

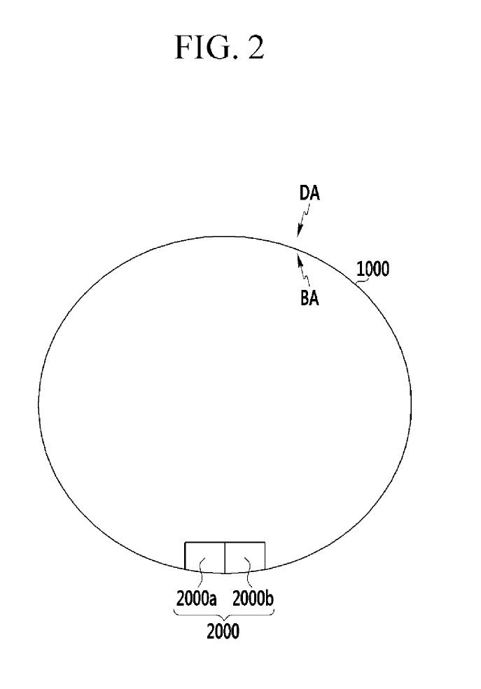

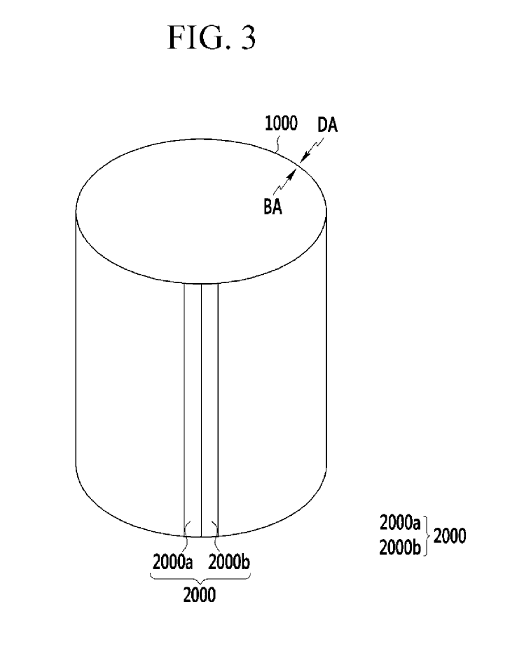

FIG. 1 is a cross-sectional view of a display device according to an exemplary embodiment. FIG. 2 is a plan view of a display device according to an exemplary embodiment implemented in a cylindrical shape. FIG. 3 is a perspective view of a display device according to an exemplary embodiment implemented in a cylindrical shape.

Referring to FIGS. 1 to 3, a display device according to an exemplary embodiment includes a display panel 1000, magnet parts or magnets 2000, and bonding parts or bonding layers 3000 positioned between the display panel 1000 and the magnet parts 2000.

The display panel 1000 can be bent or curved by the application of an external force while displaying an image. The display panel 1000 will be described in detail below.

The display panel 1000 includes a front surface DA on which images can be displayed and a rear surface BA opposing the front surface DA. The display panel 1000 can be bent in a direction of the rear surface BA by the application of an external force.

The magnet parts 2000 are attached to the rear surface of the display panel 1000 and magnets having different polarities are attracted due to magnetic force such that the display device can be bent or curved in the direction of the rear surface BA of the display panel 1000.

By way of example, the magnet parts 2000 can include a first magnet 2000a and a second magnet 2000b that are each positioned at different side edges of the rear surface BA.

The first magnet 2000a and the second magnet 2000b can have polarities that are different from each other. When the first magnet 2000a positioned at a left edge portion has a north (N) polarity (or a south (S) polarity) and the second magnet 2000b positioned at a right edge portion has an S polarity (or N polarity) are attached to the display panel 1000, the display panel 1000 can be bent in the direction of the rear surface BA due to the magnetic force between the first and second magnets 2000a and 2000b. That is, since the first magnet 2000a and the second magnet 2000b are attachable and detachable from each other, the display device can be bent into a cylindrical display device having a curved surface in the direction of the rear surface BA when the first magnet 2000a and the second magnet 2000b are attached to each other and can be unfolded to become a flat display device when the first magnet 2000a and the second magnet 2000b are detached from each other.

Although the magnet part 2000 is illustrated as having a long rod shape on the rear surface BA of the display panel 1000, it can be variously modified. For example, the magnet part 2000 can have a curved rod shape or a rod shape in which a curved surface and a straight line are combined.

The magnet part 2000 can include an electromagnet as well as a permanent magnet. The first magnet 2000a can be formed as the electromagnet and the second magnet 2000b can be formed as the permanent magnet. In this embodiment, the permanent magnet can be formed by winding coils around a core and can separately include a power source that can supply a current to the coils.

The bonding parts 3000 are interposed between the display panel 1000 and the magnet parts 2000 and attach the display panel 1000 to the magnet parts 2000.

In order to prevent the signals applied to signal lines of the display panel 1000 from being influenced by the electric field generated from the magnet part 2000, the bonding parts 3000 can include an insulating material that insulates the magnet parts 2000 from the display panel 1000. That is, according to at least one embodiment, the bonding parts 3000 are formed of an insulating adhesive so as to block the electric field generated from the magnet parts 2000 from influencing the operations of the display panel 1000.

For example, the bonding parts 3000 can be formed of polyethylene terephthalate (PET) or a polyethylene based resin. However, the specific materials used to form the bonding part 3000 are not limited thereto, but materials having insulating characteristics and bonding characteristics can be used.

In addition, the display panel 1000 and the magnet part 2000 can be formed so as to be spaced apart from each other by a distance D of about 100 Å or more. That is, by forming the bonding part 3000 positioned between the display panel 1000 and the magnet part 2000 so as to have a thickness of 100 Å or more, it is possible to protect the display panel 1000 from the electric field generated from the magnet part 2000.

Hereinafter, structures having various forms that can be attached to and detached from the display device according to an exemplary embodiment will be described.

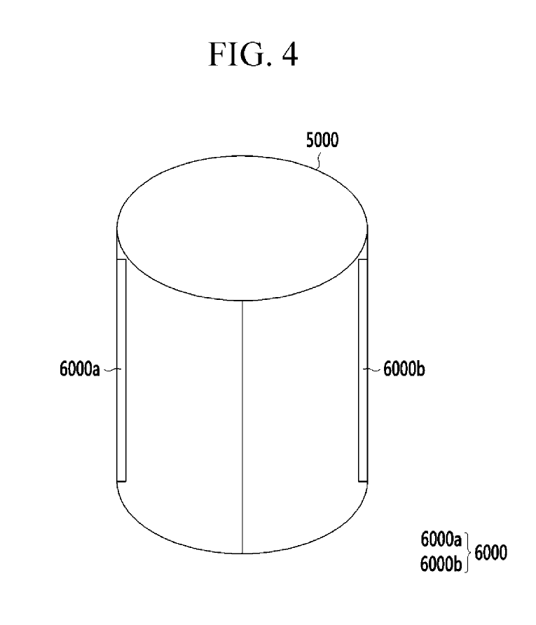

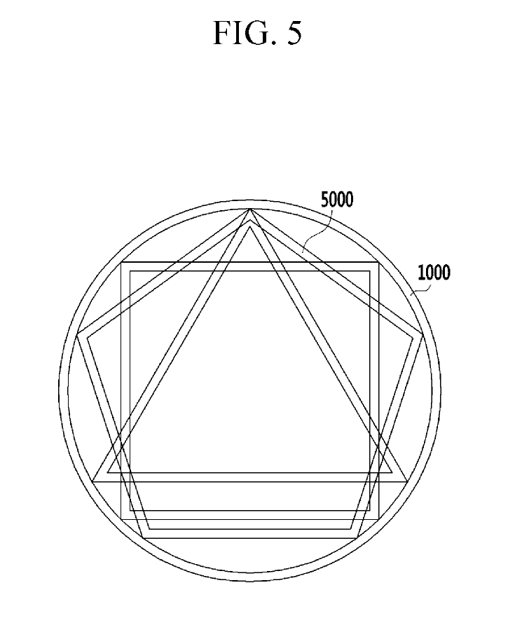

FIG. 4 is a perspective view of a structure that can be attached to and detached from a display device according to an exemplary embodiment. FIG. 5 is a diagram illustrating various shapes of a structure that can be attached to and detached from a display device according to an exemplary embodiment.

Referring to FIG. 4, the display device can be attached to and detached from a cylindrical structure 5000.

The cylindrical structure 5000 includes a magnet 6000 which can be attached to and detached from the magnet part 2000 of the display device.

The magnet 6000 of the structure 5000 may include a third magnet 6000a and a fourth magnet 6000b which are each positioned to be spaced apart from each other by a predetermined distance.

In the embodiment of FIG. 4, the third magnet 6000a of the structure can be arranged at a position that aligns with the first magnet 2000a of the display device and the fourth magnet 6000b of the structure can be arranged at a position that aligns with the second magnet 2000b of the display device.

The first magnet 2000a of the display device can be attached to and detached from the third magnet 6000a of the structure 5000 and the second magnet 2000b of the display device can be attached to and detached from the fourth magnet 6000b of the structure 5000.

The first magnet 2000a of the display device and the third magnet 6000a of the structure 5000 have polarities that are different from each other and the second magnet 2000b of the display device and the fourth magnet 6000b of the structure 5000 have polarities that are different from each other. By way of example, when both the first magnet 2000a and the second magnet 2000b of the display device have an N polarity (or S polarity), both the third magnet 6000a and the fourth magnet 6000b of the structure 5000 have an S polarity (or N polarity).

When the magnet part 2000 of the display device and the magnet of the structure 5000 are attached to each other, the display device can be bent to have a cylindrical shape corresponding to the shape of the structure 5000. When the magnet part 2000 of the display device and the magnet of the structure 500 are detached from each other, the display device can be returned again to a flat shape.

Referring to FIG. 5, the display device according to an exemplary embodiment can be attached to and detached from various structures 5000 having different shapes.

The structure 5000 that can be attached to and detached from the display device can have various cross-sectional shapes such as an N-sided polygon shape as well as a cylindrical shape and an oval shape.

Although not shown, since the magnets having polarities that are different from each other are arranged at the position at which the display panel 1000 and the structure 5000 of the display device are in contact with each other, the display panel 1000 and the structure 500 can be attached to and detached from each other.

Although it is shown that the display panel 1000 of the display device can be attached to and detached from the various shapes of structure 5000 in the cylindrical shape, the display panel 1000 of the display device can be attached to and detached from the structure 5000 while being modified to have substantially the same shape as the structure 5000.

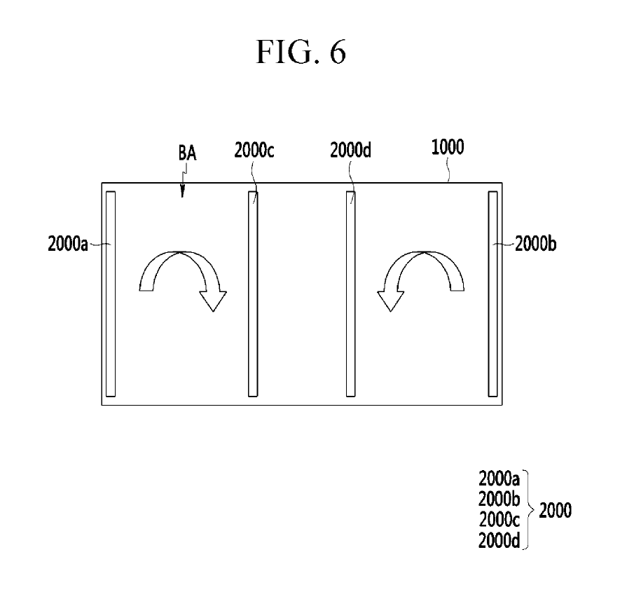

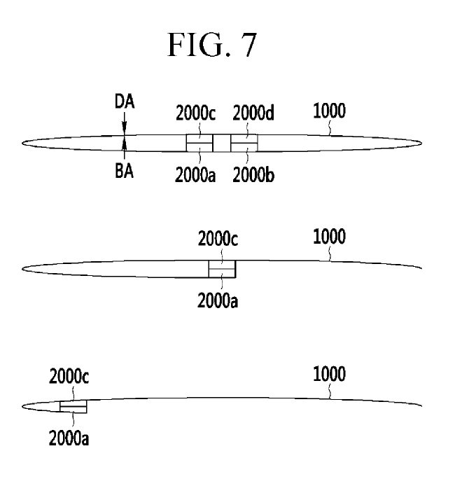

FIG. 6 is a plan view of a display device according to another exemplary embodiment. FIG. 7 is a plan view of a modified example of a display device according to another exemplary embodiment.

Referring to FIGS. 6 to 7, a display device includes a magnet part 2000 having a plurality of magnets formed on a rear surface BA of the display panel 1000.

For example, the magnet part 2000 can include a first magnet 2000a, a second magnet 2000b, a fifth magnet 2000c, and a sixth magnet 2000d that are arranged at different positions.

The first magnet 2000a and the second magnet 2000b can be each positioned at different edges of the rear surface BA and the fifth magnet 2000c and the sixth magnet 2000d can be each positioned near the center of the rear surface BA.

The first magnet 2000a and the second magnet 2000b can be attached to and detached from each other while having polarities that are different from each other. The fifth magnet 2000c and the sixth magnet 2000d can be attached to and detached from each other while having polarities that are different from each other.

The display device has a left side that can be bent in the direction of the rear surface BA so as to attach the first magnet 2000a to the fifth magnet 2000c and a right side that can be bent in the direction of the rear surface BA so as to attach the second magnet 2000b to the sixth magnet 2000d.

As such, since the display device according has the front surface DA that can display images from both the front and the rear when folded, it can display the images in both directions.

The display device according to an exemplary embodiment as described above may be modified and applied to various forms depending on the positions of the magnet part 2000.

By way of example, the display device can include only the first magnet 2000a and the fifth magnet 2000c that have polarities that are different from each other. By variously modifying the positions of the first magnet 2000a and the fifth magnet 2000c, a region at which the display panel 1000 is folded can be adjusted.

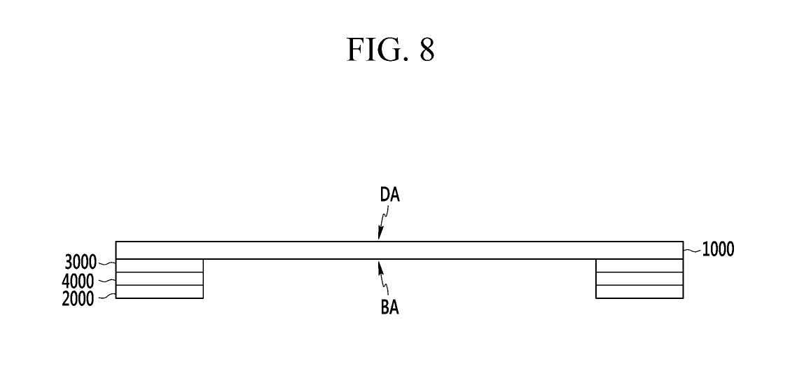

FIG. 8 is a cross-sectional view of a display device according to still another exemplary embodiment. The display device shown in FIG. 8 is the same as the display device shown in FIG. 1 as described above, except that insulating layers 4000 are added. Therefore, the same configurations are denoted by the same reference numerals and repetitive descriptions thereof will be omitted.

Referring to FIG. 8, the display device includes a display panel 1000, magnet parts 2000, bonding parts 3000, and insulating layers 4000.

The insulating layers 4000 can be positioned between the bonding parts 3000 and the magnet parts 2000.

In this embodiment, the insulating layer 4000 can be formed of an insulating material in order to protect the display panel 1000 from the magnetic field of the magnet part 2000 as described above. For example, the insulating material may be a SU-8 photoresist. However, the insulating material is not limited thereto, and any material can be used as long as the insulating layer 4000 can insulate the display panel 1000 from the magnetic field of the magnet part 2000.

The bonding parts 3000 can be positioned between the display panel 1000 and the insulating layers 4000 and can attach the insulating layers 4000 and the display panel 1000. A silicon based bonding part 3000 can be used for the bonding parts 3000.

However, the described technology is not limited thereto.

Hereinafter, the display panel of the display device according to an exemplary embodiment will be schematically described.

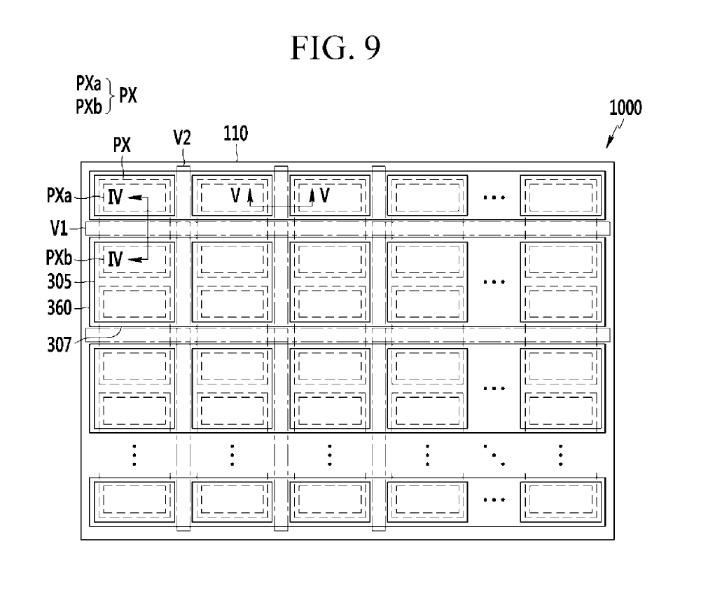

FIG. 9 is a plan view showing a display panel 2000 according to an exemplary embodiment.

The display device includes a substrate 110 formed of a material such as glass, plastic, or the like.

The substrate 110 includes a plurality of pixel regions PX. The pixel regions PX are arranged in a matrix including a plurality of pixel rows and a plurality of pixel columns. Each pixel region PX can include a first sub-pixel region PXa and a second sub-pixel region PXb. The first sub-pixel region PXa and the second sub-pixel region PXb can be vertically arranged.

A microcavity 305 covered by a roof layer or covering layer 360 is formed on the substrate 110. The roof layers 360 can be connected in a row direction and one roof layer 360 can form a plurality of micro cavities 305.

A first valley V1 is positioned between the first sub-pixel region PXa and the second sub-pixel region PXb along a row direction of the pixels and a second valley V2 is positioned between the plurality pixel columns.

A plurality of roof layers 360 are separated from each other while having the first valley V1 therebetween. At a portion that the microcavity 305 that is connected to the first valley V1, the microcavity 305 is not covered by the roof layer 360 and can be exposed to the environment. This is referred to as a liquid crystal injection hole 307.

Each roof layer 360 is formed so as to be spaced apart from the substrate 110 between second valleys V2 that are adjacent to each other, thereby forming the micro cavity 305. In addition, each roof layer 360 is formed so as to be attached to the substrate 110 in the second valley V2, thereby covering opposing sides of the micro cavity 305.

The structure of the display device described above is merely illustrative and can be variously modified. For example, the layout of the pixel region PX, the first valley V1, and the second valley V2 can be changed, the roof layers 360 can also be connected to each other in the first valley V1, and a subset of the respective roof layers 360 can be formed so as to be spaced apart from the substrate 110 in the second valley V2, such that the microcavities 305 that are adjacent to each other are also connected to each other.

Next, one pixel of the display panel according to an exemplary embodiment will be briefly described with reference to FIGS. 9 to 12.

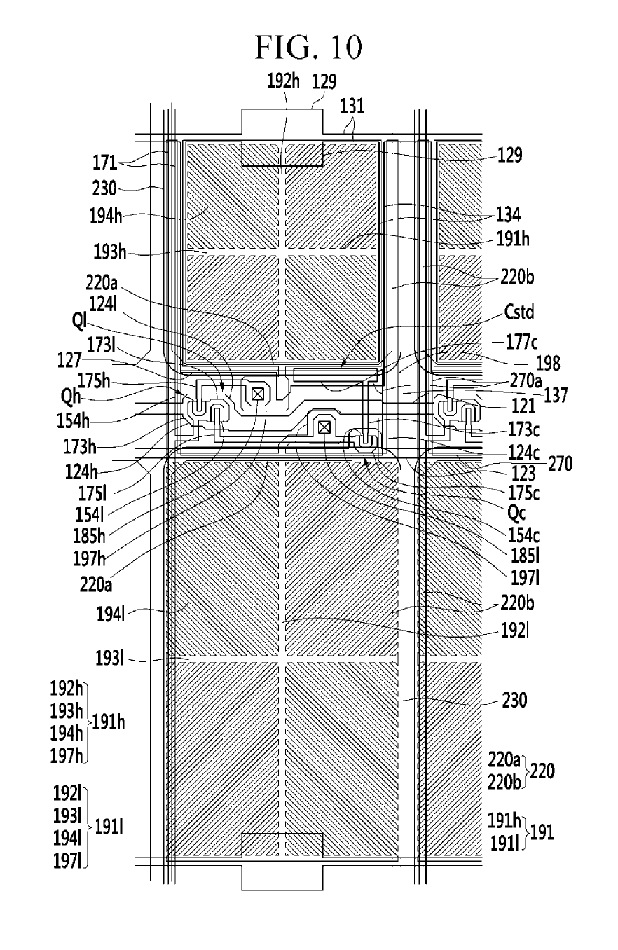

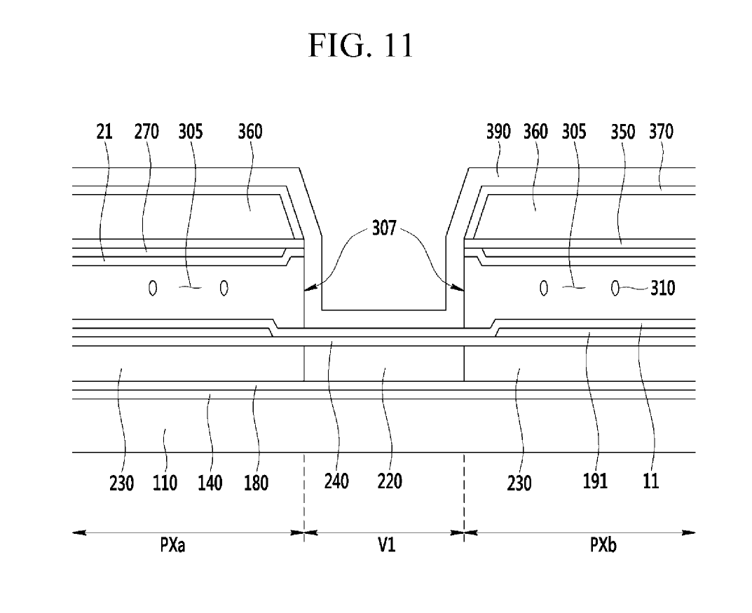

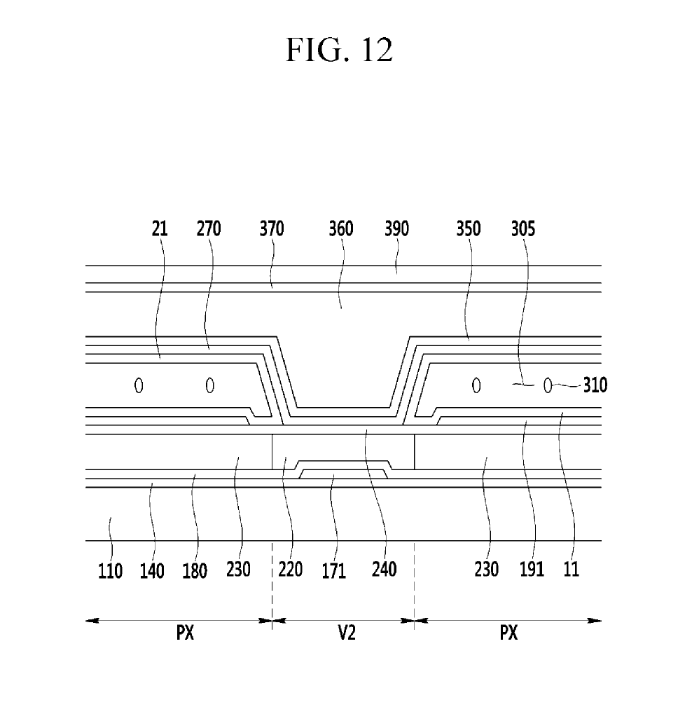

FIG. 10 is a plan view showing one pixel of the display panel according to an exemplary embodiment. FIG. 11 is a cross-sectional view showing a portion of the display panel according to an exemplary embodiment taken along line IV-IV of FIG. 9. FIG. 12 is a cross-sectional view showing a portion of the display panel according to an exemplary embodiment taken along line V-V of FIG. 9.

Referring to FIGS. 9 to 12, a plurality of gate conductors including a plurality of gate lines 121, a plurality of step-down gate lines 123, and a plurality of sustain electrode lines 131 are formed on the substrate 110.

The gate line 121 and the step-down gate line 123 are mainly extended in a horizontal direction and apply a gate signal. The gate conductor further includes a first gate electrode 124h and second gate electrode 124l which vertically protrude from the gate line 121 and a third gate electrode 124c which upwardly protrudes from the step-down gate line 123. The first gate electrode 124h and the second gate electrode 124l are connected to each other, so as to form one protrusion part. In some embodiments, the protruded shapes of the first to third gate electrodes 124h, 1241, and 124c can be changed.

The sustain electrode line 131 is also mainly extended in the horizontal direction and applies a set voltage such as a common voltage Vcom, or the like. The sustain electrode line 131 includes a vertically protruding sustain electrode 129, a pair of vertical parts 134 which are downwardly extended so as to be substantially perpendicular to the gate line 121, and a horizontal part 127 connecting ends of the pair of vertical parts 134 to each other. The horizontal part 127 includes a capacitive electrode 137 which is downwardly extended.

A gate insulating layer 140 is formed on the gate conductors 121, 123, 124h, 124l, 124c, and 131. The gate insulating layer 140 can be formed of an inorganic insulating material such as silicon nitride (SiNx), silicon oxide (SiOx), or the like. In addition, the gate insulating layer 140 can be formed of a single layer or multiple layers.

A first semiconductor 154h, a second semiconductor 154l, and a third semiconductor 154c are formed on the gate insulating layer 140. The first semiconductor 154h can be positioned on the first gate electrode 124h, the second semiconductor 154l can be positioned on the second gate electrode 124l, and the third semiconductor 154c can be positioned on the third gate electrode 124c. The first semiconductor 154h and the second semiconductor 154l can be connected to each other and the second semiconductor 154l and the third semiconductor 154c can also be connected to each other. In addition, the first semiconductor 154h can also be formed to be extended up to below the date line 171. The first to third semiconductors 154h, 154l, and 154c can be formed of an amorphous silicon, a polycrystalline silicon, a metal oxide, or the like.

Ohmic contacts (not shown) can be further formed on the first to third semiconductors 154h, 154l, and 154c, respectively. The ohmic contacts can be formed of silicide or a material such as n+ hydrogenated amorphous silicon which is doped with n-type impurities at high concentration.

Data conductors including the data line 171, a first source electrode 173h, a second source electrode 173l, a third source electrode 173c, a first drain electrode 175h, a second drain electrode 175l, and a third drain electrode 175c are formed on the first to third semiconductors 154h, 1541, and 154c.

The data line 171 applies a data signal and is mainly extended in a vertical direction so as to intersect with the gate line 121 and the step-down gate line 123. Each data line 171 includes the first source electrode 173h and the second source electrode 173l which are connected to each other and extended to the first gate electrode 124h and the second gate electrode 124l.

The first drain electrode 175h, the second drain electrode 175l, and the third drain electrode 175c include a wide end portion of one side and an end portion of the other side having a rod shape. The end portions having the rod shape of the first drain electrode 175h and the second drain electrode 175l are partially surrounded by the first source electrode 173h and the second source electrode 173l. The wide end portion of one side of the second drain electrode 175l is again extended so as to form the third source electrode 173c which is bent in a U-shape. The wide end portion 177c of the third drain electrode 175c overlaps the capacity electrode 137 so as to form a step-down capacitor Cstd and the end portion having the rod shape thereof is partially surrounded by the third source electrode 173c.

The first gate electrode 124h, the first source electrode 173h, and the first drain electrode 175h form a first thin film transistor Qh together with the first semiconductor 154h. The second gate electrode 124l, the second source electrode 173l, and the second drain electrode 175l form a second thin film transistor Ql together with the second semiconductor 154l. The third gate electrode 124c, the third source electrode 173c, and the third drain electrode 175c form a third thin film transistor Qc together with the third semiconductor 154c.

The first semiconductor 154h, the second semiconductor 154l, and the third semiconductor 154c can be connected to each other to be linear and can have substantially the same planar shape as the data conductors 171, 173h, 173l, 173c, 175h, 175l, 175c and the ohmic contacts therebelow, except for channel regions between the source electrodes 173h, 173l, and 173c and the drain electrodes 175h, 175l, and 175c.

The first semiconductor 154h has a portion which is not covered by the first source electrode 173h and the first drain electrode 175h and is exposed between the first source electrode 173h and the first drain electrode 175h. The second semiconductor 154l has a portion which is not covered by the second source electrode 173l and the second drain electrode 175l and is exposed between the second source electrode 173l and the second drain electrode 175l. The third semiconductor 154c has a portion which is not covered by the third source electrode 173c and the third drain electrode 175c and is exposed between the third source electrode 173c and the third drain electrode 175c.

A passivation layer 180 is formed on the data conductors 171, 173h, 173l, 173c, 175h, 175l, and 175c and the semiconductors 154h, 154l, and 154c and is exposed between the respective source electrodes 173c, 173l, and 173c and the respective drain electrodes 175h, 175l, and 175c. The passivation layer 180 can be formed of an organic insulating material or an inorganic insulating material and can be formed of a single layer or multiple layers.

A color filter 230 is formed on the passivation layer 180 in each pixel region PX. Each color filter 230 can display one of primary colors such as the three primary colors of red, green and blue. The colors that the color filter 230 can display are not limited to the three primary colors such as red, green, and blue. For example, the color filer 230 can also display colors such as cyan, magenta, yellow, and white. Unlike those shown, the color filter 230 can also be lengthily extended in the column direction along between the neighboring data lines 171.

A region between the neighboring color filters 230 is provided with a light blocking member 220. The light blocking member 220 can be formed at a boundary part between the pixel regions PX and on the thin film transistor, so as to prevent light leakage. The color filter 230 cam be formed in each of the first sub-pixel region PXa and the second sub-pixel region PXb. The light blocking member 220 can be formed between the first sub-pixel region PXa and the second sub-pixel region PXb.

The light blocking member 220 is extended along the gate line 121 and the step-down gate line 123 to be vertically extended. The light blocking member 220 includes a horizontal light blocking member 220a covering regions in which the first thin film transistor Qh, the second thin film transistor Ql, the third thin film transistor Qc, and the like are formed, The light blocking member 220 also includes a vertical light blocking member 220b extended along the data line 171. That is, the horizontal light blocking member 220a can be formed in the first valley V1 and the vertical light blocking member 220b can be formed in the second valley V2

The color filter 230 and the light blocking member 220 can overlap each other in some regions.

The first insulating layer 240 can be further formed on the color filter 230 and the light blocking member 220. The first insulating layer 240 can be formed of an inorganic insulating material such as silicon nitride (SiNx), silicon oxide (SiOx), silicon oxynitride (SiOxNy), or the like. The first insulating layer 240 serves to protect the color filter 230 and the light shielding member 220 which are formed of an organic material, and can be omitted, if necessary.

The first insulating layer 240 serves to protect the color filter 230 and the light blocking member 220 and serves to planarize an upper portion thereof at the same time. That is, before the pixel electrode 191 to be positioned on the first insulating layer 240 later is formed, the insulating layer 240 is planarized so that the pixel electrode 191 can be formed to be substantially flat.

A plurality of first contact holes 185h and a plurality of second contact holes 185l are formed in the first insulating layer 240, the light blocking member 220, and the passivation layer 180. The first and second contact holes 185h and 185l expose the wide end portion of the first drain electrode 175h and the wide end portion of the second drain electrode 175l.

The pixel electrode 191 is formed on the first insulating layer 240. The pixel electrode 191 can be formed of a transparent metal material such as indium-tin-oxide (ITO), indium-zinc-oxide (IZO), or the like.

The pixel electrodes 191 are separated from each other while having the gate line 121 and the step-down gate line 123 formed therebetween. The pixel electrodes 191 include a first sub-pixel electrode 191h and a second sub-pixel electrode 191l which are arranged at the top and bottom of the pixel region PX based on the gate line 121 and the step-down line 123 and neighbor each other in the column direction. That is, the first sub-pixel electrode 191h and the second sub-pixel electrode 191l are separated from each other while having the first valley V1 interposed therebetween. The first sub-pixel electrode 191h is positioned in the first sub-pixel region PXa and the second sub-pixel electrode 191l is positioned in the second sub-pixel region PXb.

The first sub-pixel electrode 191h and the second sub-pixel electrode 191l are each connected to the first drain electrode 175h and the second drain electrode 175l through the first contact hole 185h and the second contact hole 185l. Therefore, when the first thin film transistor Qh and the second thin film transistor Ql are in an ON state, the first sub-pixel electrode 191h and the second sub-pixel electrode 191l receive a data voltage from the first drain electrode 175h and the second drain electrode 175l.

The entire shape of each of the first sub-pixel electrode 191h and the second sub-pixel electrode 191l is a quadrangular shape and each of the first sub-pixel electrode 191h and the second sub-pixel electrode 191l includes a cross stem part including horizontal stem parts 193h and 193l and vertical stem parts 192h and 192l intersecting with the horizontal stem parts 193h and 193l. In addition, each of the first sub-pixel electrode 191h and the second sub-pixel electrode 191l includes a plurality of fine branch parts 194h and 194l and protrusion parts 197h and 197l which downwardly or upwardly protrudes from edge sides of the sub-pixel electrodes 191h and 191l.

The pixel electrode 191 is divided into four sub-regions by the horizontal stem parts 193h and 193l and the vertical stem parts 192h and 192l. The fine branch parts 194h and 194l obliquely extend from the horizontal stem parts 193h and 193l and the vertical stem parts 192h and 192l and the extension direction thereof may form an angle of approximately 45° or 135° with the gate line 121 or the horizontal step parts 193h and 193l. In addition, the directions in which the fine branch parts 194h and 194l of the two neighboring sub-regions are extended can be perpendicular to each other.

In the present exemplary embodiment, the first sub-pixel electrode 191h further includes an outer step part surrounding an outer portion and the second sub-pixel electrode 191l further includes horizontal parts positioned at upper end and lower end and left and right vertical parts 198 positioned at left and right of the first sub-pixel electrode 191h. The left and right vertical part 198 can prevent capacitive coupling, that is, coupling between the data line 171 and the first sub-pixel electrode 191h.

The layout of the pixel region, the structure of the thin film transistor, and the shape of the pixel electrode as described above are merely an example and the described technology is not limited thereto and can be variously modified.

The common electrode 270 is formed on the pixel electrode 191 so as to be spaced apart from the pixel electrode 191 by a predetermined distance. The microcavity 305 is formed between the pixel electrode 191 and the common electrode 270. That is, the microcavity 305 is surrounded by the pixel electrode 191 and the common electrode 270. The microcavity 305 can have a width and an area that are varied depending on the size and resolution of the display device.

The common electrode 270 can be formed of a transparent metal material such as indium-tin-oxide (ITO), indium-zinc-oxide (IZO), or the like. The common electrode 270 can be applied with a predetermined voltage and an electric field can be formed between the pixel electrode 191 and the common electrode 270.

A first alignment layer 11 is formed on the pixel electrode 191. The first alignment layer 11 can also be formed immediately on the first insulating layer 240 which is not covered by the pixel electrode 191.

A second alignment layer 21 is formed below the common electrode 270 so as to face the first alignment layer 11.

The first alignment layer 11 and the second alignment layer 21 can be formed of a vertical alignment layer and formed of an alignment material such as polyamic acid, polysiloxane, polyimide (PI), or the like. The first and second alignment layers 11 and 21 can be connected to each other at the edge of the pixel region PX.

A liquid crystal layer formed of liquid crystal molecules 310 is formed in the microcavity 305 positioned between the pixel electrode 191 and the common electrode 270. The liquid crystal molecules 310 can have negative dielectric constant anisotropy and can stand in a direction which is perpendicular to the substrate 110 in a state in which the electric field is not applied thereto. That is, a vertical alignment can be implemented.

The first sub-pixel electrode 191h and the second sub-pixel electrode 191l to which the data voltage is applied generate the electric field together with the common electrode so as to manipulate the direction of the liquid crystal molecules 310 positioned in the microcavity 305 between the two electrodes 191 and 270. The luminance of light passing through the liquid crystal layer is changed depending on the direction of the liquid crystal molecules determined as described above.

A second insulating layer 350 can be further formed on the common electrode 270. The second insulating layer 350 can be formed of an inorganic insulating material such as silicon nitride (SiNx), silicon oxide (SiOx), silicon oxynitride (SiOxNy), or the like, and can be omitted, if necessary.

The roof layer 360 is formed on the second insulating layer 350. The roof layer 360 can be formed of an organic material. The microcavity 305 is formed below the roof layer 360 and the roof layer 360 can be hardened by a hardening process so as to maintain the shape of the microcavity 305. That is, the roof layer 360 is formed so as to be spaced apart from the pixel electrode 191 while having the microcavity 305 therebetween.

The roof layer 360 is formed in each pixel region PX and the second valley V2 along a row of pixels and is not formed in the first valley V1. That is, the roof layer 360 is not formed between the first sub-pixel region PXa and the second sub-pixel region PXb. In each of the first sub-pixel region PXa and the second sub-pixel region PXb, the microcavity 305 is formed below each of the roof layers 360. The microcavity 305 is not formed below the roof layer 360 in the second valley V2 and the roof layer 260 is formed so as to be attached to the substrate 110. Therefore, the roof layer 360 positioned in the second valley V2 can be formed to have a greater thickness than that of the roof layer 360 positioned in each of the first sub-pixel region PXa and the second sub-pixel region PXb. An upper surface and both side surfaces of the microcavity 305 form a shape covered by the roof layer 360.

The common electrode 270, the second insulating layer 350, and the roof layer 360 are provided with injection holes 307 that expose a portion of the microcavity 305. The injection holes 307 can be formed so as to face each other at edges of the first sub-pixel region PXa and the second sub-pixel region PXb. That is, the injection holes 307 can be formed so as to expose the side surfaces of the microcavity 305 that correspond to a lower edge of the first sub-pixel region PXa and an upper edge of the second sub-pixel region PXb. Since the microcavity 305 is exposed by the injection hole 307, the alignment liquid, i.e., the liquid crystal material, or the like can be injected into the microcavity 305 through the injecting hole 307.

A third insulating layer 370 can be further formed on the roof layer 360. The third insulating layer 370 can be formed of an inorganic insulating material such as silicon nitride (SiNx), silicon oxide (SiOx), silicon oxynitride (SiOxNy), or the like. The third insulating layer 370 can be formed to cover the upper surface and the side surfaces of the roof layer 360. The third insulating layer 370 serves to protect the roof layer 360 formed of an organic material.

Hereinabove, the structure in which the third insulating layer 370 is formed on the roof layer 360 has been described, but the described technology is not limited thereto and the second insulating layer 370 can be omitted.

An overcoat 390 can be formed on the third insulating layer 370. The overcoat 390 is formed to cover the injecting hole 307 that exposes a portion of the microcavity 305 to the environment. That is, the overcoat 390 can seal the microcavity 305 so that the liquid crystal molecule formed in the microcavity 305 does not leak to the environment. Since the overcoat 390 contacts with the liquid crystal molecules 310, it can be formed of a material which does not react with the liquid crystal molecules 310. For example, the overcoat 390 can be formed of parylene, or the like.

The overcoat 390 can also be formed of a multilayer such as a bi-layer or a triple-layer. The bi-layer includes two layers formed of different materials. The triple-layer includes three layers, wherein the layers adjacent to each other are formed of different materials. For example, the overcoat 390 can include a layer of an organic insulating material and a layer made of an inorganic insulating material.

Although not shown, polarizing plates can be further formed on upper and lower surfaces of the display device. The polarizing plate can include a first polarizing plate and a second polarizing plate. The first polarizing plate can be attached onto the lower surface of the substrate 110 and the second polarizing plate can be attached onto the cover layer 390.

In this embodiment, since the second polarizing plate is attached onto the overcoat 390, the overcoat 390 has an upper portion which is flat. When the upper portion of the overcoat 390 is not flat, the polarizing plate may not be uniformly attached, and consequently, the polarizing plate may be lifted from the overcoat 390.

Since the display panel 2000 according to at least one exemplary embodiment can be implemented by the plurality of microcavities 305 in which the plurality of pixels are partitioned from each other, there is no degradation in image quality occurring when the display pane is bent or curved.

More specifically, a display panel according to a Comparative Example of may include a lower display panel including a thin film transistor, an upper display panel including a color filter, and a liquid crystal layer interposed between the upper display panel and the lower display panel. Here, when the display panel 1000 is bent, the upper display panel and the lower display panel are mis-aligned, thereby causing degradation in image quality. On the contrary, in the display panel according to at least one exemplary embodiment, since the pixels are implemented by the microcavities 305 which are partitioned from each other and the microcavities 305 are covered by the overcoat 390, a separate display panel is not required and as a result, there is no degradation in the image quality when the display panel 1000 is bent.

Although not shown, the display device according to at least one exemplary embodiment can use a display panel which can be bent or curved by an external force, in addition to the display panel 1000 as described above. By way of example, an organic light-emitting diode (OLED) display including an anode electrode, a cathode electrode, and a light emitting layer interposed between the anode electrode and the cathode electrode so as to emit light can also be used.

It will be obvious to those skilled in the art to which the described technology pertains that the described technology is not limited to the above-mentioned exemplary embodiments and the accompanying drawings, but may be variously substituted, modified, and altered without departing from the scope and spirit of the described technology.

While the inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A flexible display, comprising:
a display panel including a front surface configured to display an image and a rear surface opposing the front surface;
first and second magnets positioned on the rear surface of the display panel; and
first and second bonding layers respectively interposed between the display panel and the first and second magnets and bonding the display panel to the magnet.

2. The flexible display of claim 1, wherein each of the bonding layers is formed of an insulating material and insulates the display panel from the first and second magnets.

3. The flexible display of claim 1, wherein the first and second magnets are arranged at different positions on the rear surface of the display panel.

4. The flexible display of claim 3, wherein the first magnet and the second magnet have polarities different from each other and are configured to contact each other when the display panel is folded in the direction of the rear surface of the display panel.

5. The flexible display of claim 3, wherein the first magnet and the second magnet have the same polarity.

6. The flexible display of claim 3, wherein:
the display panel is configured to be attached to and detached from a structure including a third magnet and a fourth magnet,
the third magnet is configured to be attached to the first magnet, and
the fourth magnet is configured to be attached to the second magnet.

7. The flexible display of claim 6, wherein the first magnet and the third magnet have polarities that are different from each other and wherein the second magnet and the fourth magnet have polarities that are different from each other.

8. The flexible display of claim 6, wherein the structure has a cylindrical shape having a cross-section with a circle or an oval shape, or a prism having an N-sided polygonal cross-section.

9. The flexible display of claim 3, wherein the at least one magnet further includes a fifth magnet and a sixth magnet that are arranged at different positions from each other on the rear surface of the display panel.

10. The flexible display of claim 9, wherein the fifth magnet has polarity that is different from that of the first magnet and the sixth magnet has polarity that is different from that of the second magnet.

11. The flexible display of claim 10, wherein the first magnet is configured to contact the fifth magnet and the second magnet is configured to contact the sixth magnet, when the display panel is folded in the direction of the rear surface of the display panel.

12. The flexible display of claim 1, further comprising an insulating layer interposed between the bonding layers and the magnets.

13. The flexible display of claim 1, wherein the display panel and the magnets are spaced apart from each other by about 100 Å or more.

14. The flexible display of claim 1, wherein the display panel is configured to be bent or curved by external force.

15. The flexible display of claim 14, wherein the display panel includes:
a plurality of pixel electrodes;
a cover layer opposing the pixel electrodes so as to form a plurality of microcavities, wherein the microcavities are separated from each other; and
a plurality of liquid crystal layers respectively arranged in the microcavities.

16. The flexible display of claim 15, further comprising a common electrode electrically insulated from the pixel electrode.

17. The flexible display of claim 15, further comprising:
a plurality of liquid crystal injection holes formed in the cover layer, wherein each of the liquid crystal injection holes is connection to a corresponding one of the microcavities; and
an overcoat formed on the cover layer so as to cover the injection holes and seal the microcavities.
